(19) United States
(12) Patent Application Publication
(10) Pub. No.: US 2024/0290916 A1
(43) Pub. Date: Aug. 29, 2024

(54) GLASS SUBSTRATE WITH SEALING MATERIAL LAYER, AND HERMETIC PACKAGING MANUFACTURING METHOD

(71) Applicant: Nippon Electric Glass Co., Ltd., Shiga (JP)

(72) Inventor: Toru SHIRAGAMI, Shiga (JP)

(21) Appl. No.: 18/565,309

(22) PCT Filed: Jun. 6, 2022
(86) PCT No.: PCT/JP2022/022811

§ 371 Date: Nov. 29, 2023

(30) Foreign Application Priority Data
Jul. 5, 2021 (JP) 2021-111479
Mar. 18, 2022 (JP) 2022-043654

(51) Int. Cl. H01L 33/48

(52) U.S. Cl. CPC H01L 33/483; H01L 2933/0033

(57) ABSTRACT

The present invention provides a glass substrate with a sealing material layer, including a glass substrate and a sealing material layer formed on the glass substrate, wherein the glass substrate has an average transmittance at a thickness of 0.2 mm in a range of from 250 nm or more to less than 300 nm of 85% or more, and wherein a difference in thermal expansion coefficient between the sealing material layer and the glass substrate in a temperature range of from 30° C. to 300° C. is 5 ppm/° C. or less.

### TECHNICAL FIELD

The present invention relates to a glass substrate with a sealing material layer and a method of producing a hermetic package.

### BACKGROUND ART

Hermetic packages each including an electronic device such as a UV LED have been utilized in various fields, such as lighting and communication, because of a long lifetime, energy saving, and the like.

In the hermetic package of this kind, in order to protect the electronic device, a package base having mounted thereon the electronic device may be covered with a glass substrate (glass cover) so that the electronic device is housed inside.

For example, in Patent Literature 1, there is a disclosure of a hermetic package including: a package base having mounted thereon an electronic device; a frame part that surrounds a periphery of the electronic device; and a cover part including a glass substrate that covers a one-end opening of the frame part. In addition, in Patent Literature 2, there is also a disclosure of a hermetic package including: a package base having formed therein a recess for accommodating an electronic device; and a cover part including a glass substrate that covers the recess.

### CITATION LIST

Patent Literature 1: WO 2015/190242 A1
Patent Literature 2: JP 2016-027610 A

### SUMMARY OF INVENTION

### Technical Problem

Incidentally, quartz has a characteristic of hardly absorbing light at a wavelength in a UV region. Accordingly, for example, when the hermetic package is a UV LED package, a quartz substrate may be used as a cover part from the viewpoint of improving a UV light transmission property.

However, when the quartz substrate is to be joined to a frame part or a package base with a general metal brazing material (e.g., gold-tin solder), there is a problem with matching in thermal expansion coefficient between these materials. That is, the thermal expansion coefficient of the quartz substrate (about 0.6 ppm) is much lower than the thermal expansion coefficient of the general metal brazing material (about 12.0 ppm), and a difference in thermal expansion coefficient between these materials is large. As a result, a residual stress occurs in a joint portion or in the vicinity thereof, and a fracture (e.g., breakage such as cracks) is liable to occur in the quartz substrate. When the quartz substrate is fractured as described above, the airtightness of a housing space in a hermetic package cannot be maintained.

An object of the present invention is to provide a glass substrate and a method of producing a hermetic package, the glass substrate and the hermetic package each being capable of maintaining high airtightness.

### Solution to Problem

The inventor of the present invention has made extensive investigations, and as a result, has found that the above-mentioned object can be achieved by forming a sealing material layer on a glass substrate having a high UV light transmittance, and by reducing a difference in thermal expansion coefficient between the glass substrate and the sealing material layer. Thus, the finding is proposed as the present invention. Specifically, according to an embodiment of the present invention, there is provided a glass substrate with a sealing material layer, comprising a glass substrate and a sealing material layer formed on the glass substrate, wherein the glass substrate has an average transmittance at a thickness of 0.2 mm in a range of from 250 nm or more to less than 300 nm of 85% or more, and wherein a difference in thermal expansion coefficient between the sealing material layer and the glass substrate in a temperature range of from 30° C. to 300° C. is 5 ppm/° C. or less. The “average transmittance at a thickness of 0.2 mm in a range of from 250 nm or more to less than 300 nm” means that, when the glass substrate has a thickness except 0.2 mm, the average transmittance is calculated by converting the thickness to 0.2 mm.

In addition, in the glass substrate with a sealing material layer according to the embodiment of the present invention, it is preferred that a ratio of an area in which the sealing material layer is formed with respect to a surface of the glass substrate on a side on which the sealing material layer is formed be from 1% to 50%.

In addition, in the glass substrate with a sealing material layer according to the embodiment of the present invention, it is preferred that the sealing material layer have a plurality of sealing patterns, and that the sealing patterns each have a closed loop shape. With this configuration, a hermetic package can be formed for each of the sealing patterns, and hence a hermetic package group (assembly of a plurality of hermetic packages) can be produced by a series of laser sealing through use of one glass substrate with a sealing material layer. Moreover, when the hermetic package group is divided and cut, a large number of hermetic packages can be simply produced. The “closed loop shape” includes not only a shape formed only of a curve, but also a shape formed of a combination of a curve and a straight line and a shape formed only of a straight line (e.g., a quadrangular shape or any other polygonal shape).

In addition, in the glass substrate with a sealing material layer according to the embodiment of the present invention, it is preferred that the sealing material layer be a sintered body of composite powder containing at least bismuth-based glass powder and ceramic powder, and that the sealing material layer have a content of bismuth-based glass of from 65 vol % to 95 vol % and a content of a ceramic of from 5 vol % to 35 vol %.

In addition, in the glass substrate with a sealing material layer according to the embodiment of the present invention, it is preferred that the sealing material layer be substantially free of a laser absorber. Herein, the phrase “sealing material layer be substantially free of a laser absorber” refers to a case in which the sealing material layer has a content of a laser absorber of less than 1 vol %.

In addition, in the glass substrate with a sealing material layer according to the embodiment of the present invention, it is preferred that the sealing material layer have an average thickness of 15 μm or less, and that a value obtained by dividing the average thickness of the sealing material layer by a thickness of the glass substrate be from 0.005 to 0.5.

In addition, in the glass substrate with a sealing material layer according to the embodiment of the present invention, it is preferred that the sealing material layer have an average width of 1,000 μm or less, and that a value obtained by dividing an average thickness of the sealing material layer by the average width of the sealing material layer be from 0.005 to 0.1.

In addition, in the glass substrate with a sealing material layer according to the embodiment of the present invention, it is preferred that the glass substrate have any shape of a rectangular shape, a circular shape, or a circular shape with an orientation flat.

It is preferred that the glass substrate have an antireflection film formed on any one surface thereof. With this configuration, a reflection loss is reduced, and the light extraction efficiency of an LED device is improved.

In addition, it is preferred that the glass substrate with a sealing material layer according to the embodiment of the present invention be used for sealing with laser light. With this configuration, thermal degradation of an electronic device is easily prevented at the time of sealing.

According to an embodiment of the present invention, there is provided a method of producing a hermetic package, comprising the steps of: preparing a package base; preparing a glass substrate with a sealing material layer having a plurality of sealing patterns; arranging the package base and the glass substrate with a sealing material layer so that the package base and the glass substrate with a sealing material layer are laminated on each other through intermediation of the sealing material layer; radiating laser light from a glass substrate side to allow the sealing material layer to soften and deform, to thereby hermetically seal the glass substrate and the package base to provide a hermetic package group; and dividing the hermetic package group to provide a plurality of hermetic packages, wherein the glass substrate with a sealing material layer is the above-mentioned glass substrate with a sealing material layer.

According to an embodiment of the present invention, there is provided a hermetic package, comprising a glass substrate and a package base hermetically integrated with each other via a sealing material layer, wherein the glass substrate has an average transmittance at a thickness of 0.2 mm in a range of from 250 nm or more to less than 300 nm of 85% or more, and wherein a difference in thermal expansion coefficient between the sealing material layer and the glass substrate in a temperature range of from 30° C. to 300° C. is 5 ppm/° C. or less.

### Advantageous Effects of Invention

According to the present invention, the glass substrate with a sealing material layer and the method of producing a hermetic package, the glass substrate with a sealing material layer and the hermetic package each being capable of maintaining high airtightness, can be provided.

### BRIEF DESCRIPTION OF DRAWINGS

FIG. 1 is a schematic sectional view for illustrating an example of a hermetic package of the present invention.

FIG. 2 is a photograph showing a glass substrate with a sealing material layer of Example 2.

### DESCRIPTION OF EMBODIMENTS

In a glass substrate with a sealing material layer of the present invention, a glass substrate has an average transmittance at a thickness of 0.2 mm in the range of from 250 nm or more to less than 300 nm of 85% or more, preferably 86% or more, 87% or more, 88% or more, 89% or more, 90% or more, or 91% or more, particularly preferably 92% or more. When the average transmittance of the glass substrate at a thickness of 0.2 mm in the range of from 250 nm or more to less than 300 nm is too low, it becomes difficult to transmit UV light therethrough, and it becomes difficult to apply the glass substrate with a sealing material layer to a hermetic package such as a UV LED package.

The average transmittance of the glass substrate at a thickness of 0.2 mm in the range of from 300 nm or more to less than 1,000 nm is preferably 89% or more, 90% or more, 91% or more, 92% or more, 93% or more, or 94% or more, particularly preferably 95% or more. When the average transmittance of the glass substrate at a thickness of 0.2 mm in the range of from 300 nm or more to less than 1,000 nm is too low, it becomes difficult to transmit visible light therethrough, and it becomes difficult to apply the glass substrate with a sealing material layer to a hermetic package such as an LED package.

A difference in thermal expansion coefficient between a sealing material layer and the glass substrate in the temperature range of from 30° C. to 300° C. is 5 ppm/° C. or less, preferably 4 ppm/° C. or less, 3.5 ppm/° C. or less, or 3.2 ppm/° C. or less, particularly preferably 3 ppm/° C. or less. When the difference in thermal expansion coefficient between the sealing material layer and the glass substrate in the temperature range of from 30° C. to 300° C. is too large, a residual stress occurs in a joint portion or in the vicinity thereof after sealing, and a fracture (e.g., breakage such as cracks) is liable to occur in the glass substrate. Moreover, when the glass substrate is fractured, there is a risk in that the airtightness of a housing space in a hermetic package may be reduced.

The thermal expansion coefficient of the glass substrate in the temperature range of from 30° C. to 300° C. is preferably 11 ppm/° C. or less, 10 ppm/° C. or less, 9 ppm/° C. or less, 8 ppm/° C. or less, 7 ppm/° C. or less, or 6 ppm/° C. or less, particularly preferably from 3 ppm/° C. to 5 ppm/° C. Particularly when a package base is formed of silicon, the thermal expansion coefficient of the glass substrate in the temperature range of from 30° C. to 300° C. is preferably 10 ppm/° C. or less, 9 ppm/° C. or less, 8 ppm/° C. or less, 7 ppm/° C. or less, or 6 ppm/° C. or less, particularly preferably from 3 ppm/° C. to 5 ppm/° C. When the thermal expansion coefficient of the glass substrate is too low, a residual stress occurs in a joint portion or in the vicinity thereof after sealing, and a fracture (e.g., breakage such as cracks) is liable to occur in the glass substrate. Moreover, when the glass substrate is fractured, there is a risk in that the airtightness of a housing space in a hermetic package may be reduced.

The glass substrate preferably comprises as a glass composition, in terms of mass %, 50% to 80% of SiO₂, 1% to 45% of Al₂O₃+B₂O₃ (total content of Al₂O₃ and B₂O₃), 0% to 25% of Li₂O+Na₂O+K₂O (total content of Li₂O, Na₂O, and K₂O), and 0% to 25% of MgO+CaO+SrO+BaO (total content of MgO, CaO, SrO, and BaO). The reasons why the contents of the components are limited as described above are described below. In the description of the content of each component, the expression “%” means “mass %” unless otherwise specified.

SiO₂ is a main component that forms the skeleton of glass. The content of SiO₂ is preferably from 50% to 80%, from 55% to 75%, or from 58% to 70%, particularly preferably from 60% to 68%. When the content of SiO₂ is too low, a Young's modulus and acid resistance are liable to be reduced. Meanwhile, when the content of SiO₂ is too high, a viscosity at high temperature is liable to be increased to reduce meltability. Besides, a devitrified crystal such as cristobalite is liable to precipitate, and a liquidus temperature is liable to be increased.

Al₂O₃ and B₂O₃ are each a component that improves devitrification resistance. The content of Al₂O₃+B₂O₃ is preferably from 1% to 40%, from 5% to 35%, or from 10% to 30%, particularly preferably from 15% to 25%. When the content of Al₂O₃+B₂O₃ is too low, the glass is liable to devitrify. Meanwhile, when the content of Al₂O₃+B₂O₃ is too high, the glass composition loses its component balance, and hence the glass is liable to devitrify contrarily.

Al₂O₃ is a component that increases the Young's modulus, and is also a component that suppresses phase separation and devitrification. The content of Al₂O₃ is preferably from 0% to 20%, from 1% to 20%, or from 3% to 18%, particularly preferably from 5% to 16%. When the content of Al₂O₃ is too low, the Young's modulus is liable to be reduced, and besides, the glass is liable to undergo phase separation or devitrification. Meanwhile, when the content of Al₂O₃ is too high, the viscosity at high temperature is liable to be increased to reduce the meltability.

B₂O₃ is a component that improves the meltability and the devitrification resistance, and is also a component that ameliorates vulnerability to flaws to improve strength. The content of B₂O₃ is preferably from 0% to 25%, from 1% to 25%, from 2% to 25%, from 3% to 25%, from 5% to 22%, or from 7% to 19%, particularly preferably from 9% to 16%. When the content of B₂O₃ is too low, the meltability and the devitrification resistance are liable to be reduced. In addition, resistance to a hydrofluoric acid-based chemical is liable to be reduced. Meanwhile, when the content of B₂O₃ is too high, the Young's modulus and the acid resistance are liable to be reduced.

Li₂O, Na₂O, and K₂O are each a component that reduces the viscosity at high temperature to remarkably improve the meltability, and that also contributes to initial melting of glass raw materials. The content of Li₂O+Na₂O+K₂O is preferably from 0% to 25%, from 1% to 20%, or from 4% to 15%, particularly preferably from 7% to 13%. When the content of Li₂O+Na₂O+K₂O is too low, the meltability is liable to be reduced. Meanwhile, when the content of Li₂O+Na₂O+K₂O is too high, there is a risk in that the thermal expansion coefficient may be improperly increased.

Li₂O is a component that reduces the viscosity at high temperature to remarkably improve the meltability, and that also contributes to initial melting of glass raw materials. The content of Li₂O is preferably from 0% to 5%, from 0% to 3%, or from 0% to 1%, particularly preferably from 0% to 0.1%. When the content of Li₂O is too low, the meltability is liable to be reduced, and besides, there is a risk in that the thermal expansion coefficient may be improperly reduced. Meanwhile, when the content of Li₂O is too high, the glass is liable to undergo phase separation.

Na₂O is a component that reduces the viscosity at high temperature to remarkably improve the meltability, and that also contributes to initial melting of glass raw materials. In addition, Na₂O is a component for adjusting the thermal expansion coefficient. The content of Na₂O is preferably from 0% to 25%, from 1% to 20%, from 3% to 18%, or from 5% to 15%, particularly preferably from 7% to 13%. When the content of Na₂O is too low, the meltability is liable to be reduced, and besides, there is a risk in that the thermal expansion coefficient may be improperly reduced. Meanwhile, when the content of Na₂O is too high, there is a risk in that the thermal expansion coefficient may be improperly increased.

K₂O is a component that reduces the viscosity at high temperature to remarkably improve the meltability, and that also contributes to initial melting of glass raw materials. In addition, K₂O is a component for adjusting the thermal expansion coefficient. The content of K₂O is preferably from 0% to 15%, 0.1% to 10%, or from 1% to 10%, particularly preferably from 3% to 5%. When the content of K₂O is too high, there is a risk in that the thermal expansion coefficient may be improperly increased.

MgO, CaO, SrO, and BaO are each a component that reduces the viscosity at high temperature to improve the meltability. The content of MgO+CaO+SrO+BaO is preferably from 0% to 25%, from 0% to 15%, from 0.1% to 12%, or from 1% to 5%. When the content of MgO+CaO+SrO+BaO is too high, the glass is liable to devitrify.

MgO is a component that reduces the viscosity at high temperature to improve the meltability, and is also a component that remarkably increases the Young's modulus among alkaline earth metal oxides. The content of MgO is preferably from 0% to 10%, from 0% to 8%, or from 0% to 5%, particularly preferably from 0% to 1%. When the content of MgO is too high, the devitrification resistance is liable to be reduced.

CaO is a component that reduces the viscosity at high temperature to remarkably improve the meltability. In addition, a raw material for introducing CaO is relatively inexpensive among those for alkaline earth metal oxides, and hence CaO is a component that achieves a reduction in raw material cost. The content of CaO is preferably from 0% to 15%, from 0.1% to 12%, or from 0.5% to 10%, particularly preferably from 1% to 5%. When the content of CaO is too high, the glass is liable to devitrify. When the content of CaO is too low, it becomes difficult to provide the above-mentioned effects.

SrO is a component that improves the devitrification resistance. The content of SrO is preferably from 0% to 7%, from 0% to 5%, or from 0% to 3%, particularly preferably from 0% to less than 1%. When the content of SrO is too high, the glass composition loses its component balance, and hence the glass is liable to devitrify contrarily.

BaO is a component that improves the devitrification resistance. The content of BaO is preferably from 0% to 10%, from 0% to 7%, from 0% to 5%, from 0% to 3%, or from 0% to less than 1%. When the content of BaO is too high, the glass composition loses its component balance, and hence the glass is liable to devitrify contrarily.

In addition to the above-mentioned components, other components may be introduced as optional components. The content of the components other than the above-mentioned components is preferably 10% or less, or 5% or less, particularly preferably 3% or less in terms of total content, from the viewpoint of appropriately providing the effects of the present invention.

ZnO is a component that improves the meltability. However, when ZnO is incorporated in a large amount in the glass composition, the glass is liable to devitrify. Accordingly, the content of ZnO is preferably from 0% to 5%, from 0% to 3%, from 0% to 1%, or from 0% to less than 1%, particularly preferably from 0% to 0.1%.

ZrO₂ is a component that improves the acid resistance. However, when ZrO₂ is incorporated in a large amount in the glass composition, the glass is liable to devitrify. Accordingly, the content of ZrO₂ is preferably from 0% to 5%, from 0% to 3%, from 0% to 1%, or from 0% to 0.5%, particularly preferably from 0.001% to 0.2%.

Fe₂O₃ and TiO₂ are each a component that reduces a transmittance in a deep UV region. The content of Fe₂O₃+TiO₂ (total content of Fe₂O₃ and TiO₂) is preferably 100 ppm or less, 80 ppm or less, from 0.1 ppm to 60 ppm, from 0.3 ppm to 40 ppm, from 0.5 ppm to 30 ppm, from 0.8 ppm to 20 ppm, or from 1 ppm to 10 ppm, particularly preferably from 2 ppm to 5 ppm. When the content of Fe₂O₃+TiO₂ is too high, the glass is colored, and the transmittance in the deep UV region is liable to be reduced. When the content of Fe₂O₃+TiO₂ is too low, it is required to use high-purity glass raw materials, which leads to a rise in batch cost.

Fe₂O₃ is a component that reduces the transmittance in the deep UV region. The content of Fe₂O₃ is preferably 100 ppm or less, 80 ppm or less, from 0.05 ppm to 60 ppm, from 0.1 ppm to 40 ppm, from 0.5 ppm to 20 ppm, or from 1 ppm to 10 ppm, particularly preferably from 2 ppm to 8 ppm. When the content of Fe₂O₃ is too high, the glass is colored, and the transmittance in the deep UV region is liable to be reduced. When the content of Fe₂O₃ is too low, it is required to use high-purity glass raw materials, which leads to a rise in batch cost.

An Fe ion in iron oxide exists in the state of being Fe²⁺ or Fe³⁺. When the ratio of Fe²⁺ is too low, the transmittance in the deep UV region is liable to be reduced. Accordingly, a mass ratio Fe²⁺/(Fe²⁺+Fe³⁺) in iron oxide is preferably 0.1 or more, 0.2 or more, 0.3 or more, or 0.4 or more, particularly preferably 0.5 or more.

TiO₂ is a component that reduces the transmittance in the deep UV region. The content of TiO₂ is preferably 100 ppm or less, 80 ppm or less, 60 ppm or less, 40 ppm or less, from 0.05 ppm to 20 ppm, or from 0.1 ppm to 10 ppm, particularly preferably from 0.5 ppm to 5 ppm. When the content of TiO₂ is too high, the glass is colored, and the transmittance in the deep UV region is liable to be reduced. When the content of TiO₂ is too low, it is required to use high-purity glass raw materials, which leads to a rise in batch cost.

Sb₂O₃ is a component that acts as a fining agent. The content of Sb₂O₃ is preferably 1,000 ppm or less, 800 ppm or less, 600 ppm or less, 400 ppm or less, 200 ppm or less, or 100 ppm or less, particularly preferably less than 50 ppm. When the content of Sb₂O₃ is too high, the transmittance in the deep UV region is liable to be reduced.

SnO₂ is a component that acts as a fining agent. The content of SnO₂ is preferably 2,000 ppm or less, 1,700 ppm or less, 1,400 ppm or less, 1,100 ppm or less, 800 ppm or less, 500 ppm or less, or 200 ppm or less, particularly preferably 100 ppm or less. When the content of SnO₂ is too high, the transmittance in the deep UV region is liable to be reduced.

F₂, Cl₂, and SO₃ are each a component that acts as a fining agent. The content of F₂+Cl₂+SO₃ is preferably from 10 ppm to 10,000 ppm. A suitable lower limit of the content range of F₂+Cl₂+SO₃ is 10 ppm or more, 20 ppm or more, 50 ppm or more, 100 ppm or more, or 300 ppm or more, particularly 500 ppm or more, and a suitable upper limit thereof is 3,000 ppm or less, 2,000 ppm or less, or 1,000 ppm or less, particularly 800 ppm or less. In addition, a suitable lower limit of the content range of each of F₂, Cl₂, and SO₃ is 10 ppm or more, 20 ppm or more, 50 ppm or more, 100 ppm or more, or 300 ppm or more, particularly 500 ppm or more, and a suitable upper limit thereof is 3,000 ppm or less, 2,000 ppm or less, or 1,000 ppm or less, particularly 800 ppm or less. When the content of those components is too low, it becomes difficult to exhibit a fining effect. Meanwhile, when the content of those components is too high, there is a risk in that a fining gas may remain in the glass as bubbles.

The size of the glass substrate is preferably 600 mm² or more or 5,000 mm² or more, particularly preferably 15,000 mm² or more. As the size becomes larger, a larger number of hermetic packages can be collected from one glass substrate, and hence the production cost of a hermetic package is easily reduced.

The thickness of the glass substrate is preferably 2.0 mm or less, 1.5 mm or less, or 1.0 mm or less, particularly preferably from 0.1 mm to 0.5 mm. When the thickness is too large, the mass of the glass substrate is increased, and it becomes difficult to handle the glass substrate. Besides, the transmittance in the deep UV region is liable to be reduced. Meanwhile, when the thickness is too small, it becomes difficult to maintain the stiffness of the glass substrate in a conveyance line, and deformation, warping, or fracture of the glass substrate is liable to occur.

A surface roughness Ra of the surface of the glass substrate is preferably 10 nm or less, 9 nm or less, 8 nm or less, 7 nm or less, 6 nm or less, 5 nm or less, 4 nm or less, 3 nm or less, or 2 nm or less, particularly preferably 1 nm or less. When the surface roughness Ra of the surface is too high, the transmittance in the deep UV region tends to be reduced. Herein, the “Ra” refers to an arithmetical mean roughness defined in JIS B0601-1994.

The glass substrate preferably has any shape of a rectangular shape, a circular shape, or a circular shape with an orientation flat. When the glass substrate has such shape, a plurality of sealing patterns are easily formed on the surface of the glass substrate. In particular, it is preferred that the glass substrate have a circular shape or a circular shape with an orientation flat because laser sealing can be performed through utilization of a semiconductor manufacturing apparatus.

A functional film may be formed on the surface of the glass substrate. In particular, an antireflection film is preferred as the functional film. With this configuration, light that reflects off the surface of the glass substrate can be reduced.

In the glass substrate with a sealing material layer of the present invention, the sealing material layer is a sintered body of a sealing material. The sealing material is generally composite powder containing glass powder and ceramic powder. Any of various glass powders may be used as the glass powder. For example, Bi₂O₃-based glass, V₂O₅-based glass, or SnO-based glass is suitable in view of a low melting point characteristic, and Bi₂O₃-based glass is particularly preferred in view of thermal stability and water resistance. The term “-based glass” as used herein refers to glass which comprises the specified components as essential components and in which the total content of the specified components is 25 mol % or more, preferably 30 mol % or more, more preferably 35 mol % or more. The glass composition of the glass powder is preferably substantially free of PbO (less than 0.1 mol %) from an environmental point of view.

The Bi₂O₃-based glass preferably comprises as a glass composition, in terms of mol %, 28% to 60% of Bi₂O₃, 15% to 37% of B₂O₃, and 1% to 30% of ZnO. The reasons why the content range of each component is limited as described above are described below. In the description of the glass composition range, the expression “%” means “mol %”.

Bi₂O₃ is a main component for reducing a softening point, and its content is preferably from 28% to 60% or from 33% to 55%, particularly preferably from 35% to 45%. When the content of Bi₂O₃ is too low, the softening point becomes too high, and hence flowability is liable to be reduced. Meanwhile, when the content of Bi₂O₃ is too high, the glass is liable to devitrify at the time of firing, and owing to the devitrification, the flowability is liable to be reduced.

B₂O₃ is a component essential as a glass-forming component, and its content is preferably from 15% to 37% or from 20% to 33%, particularly preferably from 25% to 30%. When the content of B₂O₃ is too low, a glass network is hardly formed, and hence the glass is liable to devitrify at the time of firing. Meanwhile, when the content of B₂O₃ is too high, the glass has increased viscosity, and hence the flowability is liable to be reduced.

ZnO is a component that improves the devitrification resistance, and its content is preferably from 1% to 30%, from 3% to 25%, or from 5% to 22%, particularly preferably from 9% to 20%. When the content is less than 1%, or more than 30%, the glass composition loses its component balance, and hence the devitrification resistance is liable to be reduced.

In addition to the above-mentioned components, for example, the following components may be added.

SiO₂ is a component that improves the water resistance, while having an action of increasing the softening point. Accordingly, the content of SiO₂ is preferably from 0% to 5%, from 0% to 3%, or from 0% to 2%, particularly preferably from 0% to 1%. In addition, when the content of SiO₂ is too high, the glass is liable to devitrify at the time of firing.

Al₂O₃ is a component that improves the water resistance. The content of Al₂O₃ is preferably from 0% to 10% or from 0% to 5%, particularly preferably from 0.1% to 2%. When the content of Al₂O₃ is too high, there is a risk in that the softening point may be improperly increased.

Li₂O, Na₂O, and K₂O are each a component that reduces the devitrification resistance. Accordingly, the content of each of Li₂O, Na₂O, and K₂O is from 0% to 5% or from 0% to 3%, particularly from 0% to less than 1%.

MgO, CaO, SrO, and BaO are each a component that improves the devitrification resistance, but are each a component that increases the softening point. Accordingly, the content of each of MgO, CaO, SrO, and BaO is from 0% to 20% or from 0% to 10%, particularly from 0% to 5%.

In order to reduce the softening point of the Bi₂O₃-based glass, it is required to introduce a large amount of Bi₂O₃ into the glass composition, but when the content of Bi₂O₃ is increased, the glass is liable to devitrify at the time of firing, and owing to the devitrification, the flowability is liable to be reduced. This tendency is particularly remarkable when the content of Bi₂O₃ is 30% or more. As a countermeasure for this problem, the addition of CuO and MnO can effectively suppress the devitrification of the glass even when the content of Bi₂O₃ is 30% or more. Further, when CuO is added, laser absorption characteristics at the time of laser sealing can be improved. The content of each of CuO and MnO₂ is preferably from 0% to 40%, from 5% to 35%, or from 10% to 30%, particularly preferably from 15% to 25%. When the content of each of CuO and MnO₂ is too high, the glass composition loses its component balance, and hence the devitrification resistance is liable to be reduced contrarily.

Fe₂O₃ is a component that improves the devitrification resistance and the laser absorption characteristics, and its content is preferably from 0% to 10% or from 0.1% to 5%, particularly preferably from 0.5% to 3%. When the content of Fe₂O₃ is too high, the glass composition loses its component balance, and hence the devitrification resistance is liable to be reduced contrarily.

Sb₂O₃ is a component that improves the devitrification resistance, and its content is preferably from 0% to 5%, particularly preferably from 0% to 2%. When the content of Sb₂O₃ is too high, the glass composition loses its component balance, and hence the devitrification resistance is liable to be reduced contrarily.

The glass powder has an average particle diameter D₅₀ of preferably less than 15 μm or from 0.5 μm to 10 μm, particularly preferably from 1 μm to 5 μm. As the average particle diameter D₅₀ of the glass powder becomes smaller, the softening point of the glass powder is reduced more.

The content of the ceramic powder in the sealing material is preferably from 5 vol % to 35 vol %, from 10 vol % to 33 vol %, or from 15 vol % to 30 vol %, particularly preferably from 20 vol % to 30 vol %. The content of the glass powder in the sealing material is preferably from 65 vol % to 95 vol %, from 67 vol % to 90 vol %, or from 70 vol % to 85 vol %, particularly preferably from 70 vol % to 80 vol %. When the content of the ceramic powder is too high, the content of the glass powder is relatively reduced, and it becomes difficult to ensure desired flowability and thermal stability. When the content of the ceramic powder is too low, an effect exhibited by the addition of the ceramic powder becomes poor.

The ceramic powder is preferably one kind or two or more kinds selected from, for example, β-eucryptite, cordierite, zircon, alumina, mullite, willemite, zirconium phosphate, zirconium phosphate tungstate, and zircon tungstate, particularly preferably β-eucryptite, which has a particularly high reducing effect on the thermal expansion coefficient.

Any powder material other than the glass powder and the ceramic powder may be introduced into the sealing material. In addition, glass beads, a spacer, or the like may be introduced. Herein, the glass beads and the spacer are each formed of a composition or material having high heat resistance so that the glass beads and the spacer can maintain their shapes even after sealing. In addition, in order to improve the laser absorption characteristics, a laser absorber, such as a Mn—Fe—Al-based oxide, carbon, or a Mn—Fe—Cr-based oxide, may be incorporated at from 1 vol % to 15 vol %, but it is preferred that the sealing material be substantially free of the laser absorber in consideration of the thermal stability of the sealing material.

The sealing material may be used in a powdery state, but is preferably formed into a paste by being uniformly kneaded with a vehicle from the viewpoint of improving handleability. The vehicle generally contains a solvent and a resin. The resin is added for the purpose of adjusting the viscosity of the paste. In addition, a surfactant, a thickener, or the like may also be added thereto as required. The produced paste is applied to a surface of the glass substrate by means of a coating machine, such as a dispenser or a screen printing machine.

As the resin, there may be used an acrylic acid ester (acrylic resin), ethylcellulose, a polyethylene glycol derivative, nitrocellulose, polymethylstyrene, polyethylene carbonate, a methacrylic acid ester, and the like. In particular, an acrylic acid ester or nitrocellulose is preferred because of its satisfactory thermolytic property.

As the solvent, there may be used N,N′-dimethyl formamide (DMF), α-terpineol, a higher alcohol, γ-butyrolactone (γ-BL), tetralin, butylcarbitol acetate, ethyl acetate, isoamyl acetate, diethylene glycol monoethyl ether, diethylene glycol monoethyl ether acetate, benzyl alcohol, toluene, 3-methoxy-3-methylbutanol, water, triethylene glycol monomethyl ether, triethylene glycol dimethyl ether, dipropylene glycol monomethyl ether, dipropylene glycol monobutyl ether, tripropylene glycol monomethyl ether, tripropylene glycol monobutyl ether, propylene carbonate, dimethyl sulfoxide (DMSO), N-methyl-2-pyrrolidone, and the like. In particular, α-terpineol is preferred because of its high viscosity and satisfactory solubility of a resin and the like.

The thermal expansion coefficient of the sealing material layer in the temperature range of from 30° C. to 300° C. is preferably from 50 ppm/° C. to 90 ppm/° C. or from 55 ppm/° C. to 80 ppm/° C., particularly preferably from 60 ppm/° C. to 75 ppm/° C. Particularly when a package base is formed of silicon, the thermal expansion coefficient of the sealing material layer in the temperature range of from 30° C. to 300° C. is preferably from 60 ppm/° C. to 80 ppm/° C. or from 65 ppm/° C. to 75 ppm/° C., particularly preferably from 68 ppm/° C. to 73 ppm/° C. When the thermal expansion coefficient of the sealing material layer is too high, a residual stress occurs in a joint portion or in the vicinity thereof after sealing, and a fracture (e.g., breakage such as cracks) is liable to occur in the glass substrate. Moreover, when the glass substrate is fractured, there is a risk in that the airtightness of a housing space in a hermetic package may be reduced. Meanwhile, when the thermal expansion coefficient of the sealing material layer is too low, the ratio of a refractory filler is increased, and hence the softening flowability of the sealing material is reduced, with the result that a hermetic defect or the like is liable to occur in a hermetic package.

The thermal expansion coefficient of a package base in the temperature range of from 30° C. to 300° C. is preferably 10 ppm/° C. or more or 20 ppm/° C. or more, particularly preferably from 30 ppm/° C. to 60 ppm/° C. When the thermal expansion coefficient of the package base is too low, a residual stress occurs in a joint portion or in the vicinity thereof after sealing, and a hermetic defect is liable to occur in a hermetic package.

When the average thickness of the sealing material layer is 15 μm or less, a difference in thermal expansion coefficient between the glass substrate and the package base in the temperature range of from 30° C. to 300° C. is preferably 6.5 ppm/° C. or less, 4.5 ppm/° C. or less, 3.5 ppm/° C. or less, or 2.0 ppm/° C. or less, particularly preferably 1.0 ppm/° C. or less. When the average thickness of the sealing material layer is 15 μm or less, in the case where the difference in thermal expansion coefficient between the glass substrate and the package base in the temperature range of from 30° C. to 300° C. is too large, a residual stress occurs in a joint portion or in the vicinity thereof after sealing, and a fracture (e.g., breakage such as cracks) is liable to occur in the glass substrate. Moreover, when the glass substrate is fractured, there is a risk in that the airtightness of a housing space in a hermetic package may be reduced.

A difference in thermal expansion coefficient between the sealing material layer and the package base in the temperature range of from 30° C. to 300° C. is preferably 5.5 ppm/° C. or less or 4.0 ppm/° C. or less, particularly preferably 3.5 ppm/° C. or less. When the difference in thermal expansion coefficient between the sealing material layer and the package base in the temperature range of from 30° C. to 300° C. is too large, a residual stress occurs in a joint portion or in the vicinity thereof after sealing, and a hermetic defect is liable to occur in a hermetic package.

The package base preferably has a recess capable of housing an electronic device. With this configuration, the electronic device such as a sensor device is easily housed in the recess of the package base. The recess of the package base is preferably formed in a frame shape along a peripheral end edge region of the package base. With this configuration, an effective area for functioning as a device can be enlarged. In addition, the electronic device is easily housed in a space in the package base, and for example, wire joining is easily performed.

The package base is preferably formed of any one of a metal such as silicon, a glass ceramic, aluminum nitride, or aluminum oxide, or a composite material thereof (e.g., a composite material in which aluminum nitride and a glass ceramic are integrated with each other). In particular, silicon is preferred because silicon has a satisfactory heat dissipating property and facilitates the formation of the recess through etching or the like.

The average thickness of the sealing material layer is preferably 15 μm or less or less than 8.0 μm, particularly preferably 1.0 μm or more and less than 7.0 μm. A value obtained by dividing the average thickness of the sealing material layer by the average width of the sealing material layer is preferably from 0.005 to 0.1, particularly preferably from 0.01 to 0.05. A value obtained by dividing the average thickness of the sealing material layer by the thickness of the glass substrate is preferably from 0.005 to 0.5, particularly preferably from 0.01 to 0.1. When the average thickness of the sealing material layer, the value obtained by dividing the average thickness of the sealing material layer by the average width of the sealing material layer, and the value obtained by dividing the average thickness of the sealing material layer by the thickness of the glass substrate are outside the above-mentioned ranges, the accuracy of laser sealing is liable to be reduced. Meanwhile, when those values fall within the above-mentioned ranges, in the case where the thermal expansion coefficients of the sealing material layer and the glass substrate do not match with each other, a stress remaining in a sealed portion after laser sealing can be reduced. As a method of controlling the average thickness of the sealing material layer as describe above, there are given: a method involving thinly applying a sealing material paste; and a method involving subjecting the surface of the sealing material layer to polishing treatment.

The average width of the sealing material layer is preferably 1 μm or more and 1,000 μm or less, particularly preferably 100 μm or more and 800 μm or less. When the average width of the sealing material layer is narrowed, a stress remaining in a sealed portion after laser sealing can be easily reduced. Meanwhile, when the maximum width of the sealing material layer is excessively narrowed, in the case where a large shear stress is applied to the sealing material layer, the sealing material layer is liable to undergo bulk fracture. Further, the accuracy of laser sealing is liable to be reduced.

The ratio of an area in which the sealing material layer is formed with respect to the surface of the glass substrate on a side on which the sealing material layer is formed is preferably from 1% to 50%, from 10% to 48%, from 20% to 45%, or from 23% to 43%, particularly preferably from 25% to 40%. When the ratio of the area of the surface in which the sealing material layer is formed is high, a residual stress occurs in a joint portion or in the vicinity thereof after sealing, and a fracture (e.g., breakage such as cracks) is liable to occur in the glass substrate. Meanwhile, when the ratio of the area in which the sealing material layer is formed is high, a large number of sealing patterns can be formed, that is, a large number of hermetic packages can be produced from one substrate. In the glass substrate with a sealing material layer of the present invention, the difference in thermal expansion coefficient between the sealing material layer and the glass substrate is strictly specified, and hence, even when the ratio of the area in which the sealing material layer is formed is increased, a residual stress occurring in a joint portion or in the vicinity thereof after sealing can be reduced.

In the glass substrate with a sealing material layer of the present invention, it is preferred that the sealing material layer have a plurality of sealing patterns, and the sealing patterns each have a closed loop shape. With this configuration, a hermetic package group can be obtained. When the hermetic package group is divided, hermetic packages in accordance with the number of sealing patterns can be produced efficiently. The number of the sealing patterns is preferably from 50 to 5,000 or from 80 to 3,000, particularly preferably from 200 to 2,500.

A method of producing a hermetic package of the present invention comprises the steps of: preparing a package base; preparing a glass substrate with a sealing material layer having a plurality of sealing patterns; arranging the package base and the glass substrate with a sealing material layer so that the package base and the glass substrate with a sealing material layer are laminated on each other through intermediation of a sealing material layer; radiating laser light from a glass substrate side to allow the sealing material layer to soften and deform, to thereby hermetically seal the glass substrate and the package base to provide a hermetic package group; and dividing the hermetic package group to provide a plurality of hermetic packages, wherein the glass substrate with a sealing material layer is the above-mentioned glass substrate with a sealing material layer.

In the step of arranging the package base and the glass substrate so that the package base and the glass substrate are laminated on each other, the glass substrate may be arranged under the package base, but from the viewpoint of the efficiency of laser sealing, the glass substrate is preferably arranged above the package base.

Various lasers may each be used as the laser to be radiated from the glass substrate side. In particular, a semiconductor laser, a YAG laser, a CO₂ laser, an excimer laser, and an infrared laser are preferred because those lasers are easy to handle.

The beam shape of the laser light at the time of laser sealing is not particularly limited. A common beam shape includes a circle, an ellipse, and a rectangle, but any other shape may be adopted. In addition, the beam diameter of the laser light at the time of laser sealing is preferably from 100 mm to 1,000 mm.

An atmosphere for performing the laser sealing is not particularly limited. An air atmosphere or an inert atmosphere such as a nitrogen atmosphere may be adopted.

Before the laser sealing, the package base is preferably preheated at a temperature equal to or higher than 100° C. and equal to or lower than the temperature limit of an electric device. With this configuration, thermal conduction toward a package base side can be inhibited at the time of laser sealing, and hence the laser sealing can be performed efficiently.

The laser sealing is preferably performed under the state in which the glass substrate is pressed. With this configuration, the softening and deformation of the sealing material layer can be promoted at the time of laser sealing.

The method of producing a hermetic package preferably further comprises a step of housing an electric device in the recess of the package base before arranging the package base and the glass substrate so that the package base and the glass substrate are laminated on each other.

A hermetic package of the present invention comprises a glass substrate and a package base hermetically integrated with each other via a sealing material layer, wherein the glass substrate has an average transmittance at a thickness of 0.2 mm in the range of from 250 nm or more to less than 300 nm of 85% or more, and wherein a difference in thermal expansion coefficient between the sealing material layer and the glass substrate in the temperature range of from 30° C. to 300° C. is 5 ppm/° C. or less. The technical features of the technical package of the present invention have already been described above, and hence detailed description thereof is omitted here.

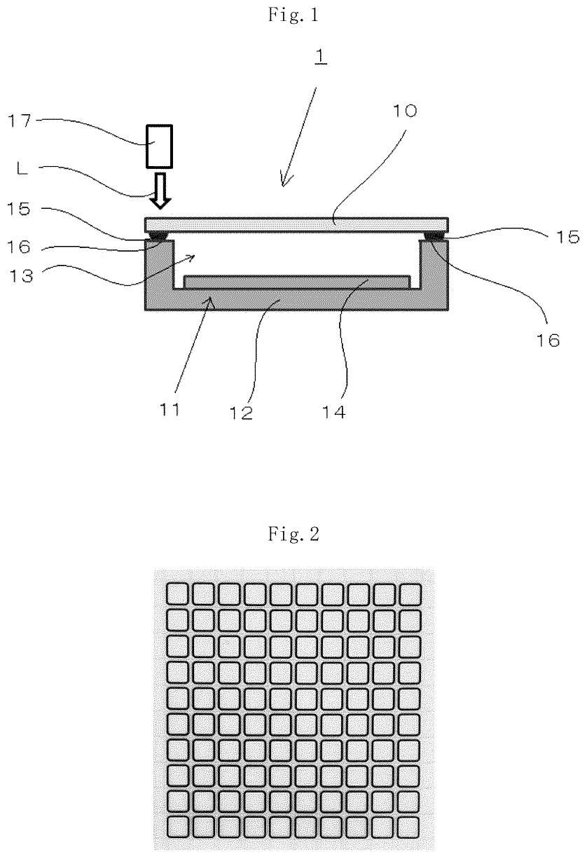

Now, an embodiment of the present invention is described with reference to the drawings. FIG. 1 is a schematic sectional view for illustrating an example of the hermetic package of the present invention. A hermetic package 1 comprises a glass substrate 10 and a package base 11. The package base 11 comprises a base part 12 and further comprises a frame part on an outer peripheral edge portion of the base part 12, and thus has formed therein a recess 13. In addition, an electric device 14 is housed in the recess 13 of the package base 11. Electric wiring (not shown) that electrically connects the electric device 14 to an outside is formed in the package base 11.

A sealing material layer 15 in a frame shape is formed on the surface of the glass substrate 10. The width of the sealing material layer 15 is smaller than the width of a top 16 of the frame part of the package base 11.

The glass substrate 10 and the package base 11 are arranged to be laminated on each other so that the sealing material layer 15 of the glass substrate 10 corresponds to a center line in a width direction of the top 16 of the frame part of the package base 11. After that, laser light L emitted from a laser irradiation apparatus 17 is radiated along the sealing material layer 15 from a glass substrate 10 side. Thus, the sealing material layer 15 softens and flows, and then the glass substrate 10 and the package base 11 are hermetically sealed with each other. Thus, a hermetic structure of the hermetic package 1 is formed.

### EXAMPLES

### Example 1

Now, the present invention is described in detail by way of Examples. The following Examples are merely illustrative. The present invention is by no means limited to the following Examples.

### (Sample No. 1)

First, a silicon substrate (thermal expansion coefficient in the range of from 30° C. to 300° C.: 3.8 ppm/° C., □4 mm) was prepared.

Next, a glass substrate formed of alkali borosilicate glass (thermal expansion coefficient in the range of from 30° C. to 300° C.: 4.2 ppm/° C., □4 mm, thickness: 0.2 mm) was prepared. The glass substrate comprises as a glass composition, in terms of mass, 70% of SiO₂, 5.9% of Al₂O₃, 18% of B₂O₃, 1% of Li₂O, 2% of Na₂O, 3% of K₂O, 0.1% of Cl, 0.0001% of TiO₂, and 0.0001% of Fe₂O₃, has an average transmittance at a thickness of 0.2 mm in the range of from 250 nm or more to less than 300 nm of 91%, and has an average transmittance at a thickness of 0.2 mm in the range of from 300 nm or more to less than 1,000 nm of 92%.

In addition, bismuth-based glass powder and ceramic powder were mixed at a ratio of 73 vol %:27 vol % to produce a sealing material. In this case, the bismuth-based glass powder had an average particle diameter D₅₀ of 1.0 μm and a 99% particle diameter D₉₉ of 2.8 μm, and the ceramic powder had an average particle diameter D₅₀ of 1.0 μm and a 99% particle diameter D₉₉ of 2.8 μm. The bismuth-based glass comprises as a glass composition, in terms of mol, 36.5% of Bi₂O₃, 28.5% of B₂O₃, 9.5% of ZnO, 1.5% of Al₂O₃, 9.5% of MnO₂, 13.6% of CuO, and 0.9% of Fe₂O₃. In addition, the ceramic powder is β-eucryptite.

The obtained sealing material was measured for a thermal expansion coefficient. As a result, the thermal expansion coefficient was 7.1 ppm/° C. The thermal expansion coefficient is a value measured with a push-rod type TMA apparatus in a measurement temperature range of from 30° C. to 300° C.

Next, the sealing material was applied onto the glass substrate, followed by drying, binder removal, and sintering. Thus, a sealing material layer having a closed loop shape was formed. Specifically, first, the above-mentioned sealing material, a vehicle, and a solvent were kneaded so as to achieve a viscosity within the range of 90±20 Pa·s (25° C., shear rate: 4), and then further kneaded with a triple roll mill until powders were homogeneously dispersed to be formed into a paste. Thus, a sealing material paste was obtained. A vehicle obtained by dissolving an ethylcellulose organic resin in a glycol ether-based solvent was used as the vehicle. Next, the sealing material paste was printed in a frame shape on the outer peripheral edge portion of the glass substrate with a screen printing machine. Further, the sealing material paste was dried at 110° C. for 10 minutes under an air atmosphere to provide a dried film. After that, the dried film was subjected to binder removal and sintering through heat treatment at 350° C. for 15 minutes and then at 500° C. for 10 minutes in an electric furnace. Thus, a sealing material layer having an average width of about 400 μm and an average thickness of about 5 μm was formed.

Finally, the glass substrate on which the sealing material layer had been sintered and the silicon substrate were laminated on each other, and laser light was radiated from a glass substrate side to allow the sealing material layer to soften and flow, to thereby hermetically integrate the glass substrate and the silicon substrate with each other. Thus, a hermetic package was obtained. The output, scanning speed, and beam diameter of the laser are 10 W, 15 mm/sec, and φ500 μm, respectively.

### (Sample No. 2)

A hermetic package was obtained in the same manner as in Sample No. 1 except that a glass substrate formed of alkali borosilicate glass (thermal expansion coefficient in the range of from 30° C. to 300° C.: 9.9 ppm/° C., □4 mm, thickness: 0.2 mm) was used in place of the glass substrate according to Sample No. 1. The glass substrate comprises as a glass composition, in terms of mass %, 70.2% of SiO₂, 1.6% of Al₂O₃, 2.3% of B₂O₃, 9.6% of Na₂O, 9.1% of K₂O, 7.0% of BaO, 0.4% of Cl, 0.1% of SrO, 0.0001% of TiO₂, and 0.0001% of Fe₂O₃, has an average transmittance at a thickness of 0.2 mm in the range of from 250 nm or more to less than 300 nm of 89%, and has an average transmittance at a thickness of 0.2 mm in the range of from 300 nm or more to less than 1,000 nm of 92%.

### (Sample No. 3)

A hermetic package was obtained in the same manner as in Sample No. 1 except that a quartz substrate (thermal expansion coefficient in the range of from 30° C. to 300° C.: 0.6 ppm/° C., □4 mm, thickness: 0.5 mm) was used in place of the glass substrate according to Sample No. 1.

### (Evaluation)

For each of the hermetic packages obtained in Samples No. 1 to 3, the presence or absence of cracks was observed, and a temperature cycle test and a pressure cooker test were performed. The results are shown in Table 1.

TABLE 1

| | Sample | Sample | Sample |
|---|---|---|---|
| | No. 1 | No. 2 | No. 3 |
| Presence or absence | Absent | Absent | Present |
| of cracks | | | |
| Temperature | ∘ | ∘ | x |
| cycle test | | | |
| Pressure | ∘ | ∘ | x |
| cooker test | | | |

The presence or absence of cracks was evaluated as follows: in the obtained hermetic package, the vicinity of the sealing material layer was observed with an optical microscope.

The temperature cycle test was evaluated as follows: the obtained hermetic package was repeatedly subjected to a temperature cycle under the conditions of 125° C.↔−55° C. and 1,000 cycles, and then the vicinity of the sealing material layer was observed; and a case in which alternation, cracks, peeling, and the like were not observed was represented by Symbol “◯”, and a case in which alternation, cracks, peeling, and the like were observed was represented by Symbol “x”.

The pressure cooker test (PCT) was evaluated as follows: the obtained hermetic package was retained under an environment at high temperature, high humidity, and high pressure under the conditions of 121° C., a humidity of 100%, 2 atm, and 24 hours, and then the vicinity of the sealing material layer was observed; and a case in which alternation, cracks, peeling, and the like were not observed was represented by Symbol “◯”, and a case in which alternation, cracks, peeling, and the like were observed was represented by Symbol “x”.

As apparent from Table 1, the hermetic packages obtained in Sample No. 1 and Sample No. 2 received satisfactory evaluations for the presence or absence of cracks, the temperature cycle test, and the pressure cooker test. Meanwhile, the hermetic package obtained in Sample No. 3 received poor evaluations for the presence or absence of cracks, the temperature cycle test, and the pressure cooker test.

### Example 2

A glass substrate formed of alkali borosilicate glass (thermal expansion coefficient in the range of from 30° C. to 300° C.: 4.2 ppm/° C., thickness: 0.2 mm, □44 mm) was prepared. The glass substrate comprises as a glass composition, in terms of mass %, 70% of SiO₂, 5.9% of Al₂O₃, 18% of B₂O₃, 1% of Li₂O, 2% of Na₂O, 3% of K₂O, 0.1% of Cl, 0.0001% of TiO₂, and 0.0001% of Fe₂O₃, has an average transmittance at a thickness of 0.2 mm in the range of from 250 nm or more to less than 300 nm of 91%, and has an average transmittance at a thickness of 0.2 mm in the range of from 300 nm or more to less than 1,000 nm of 92%. 100 Sealing patterns each having a closed loop shape of □3.3 mm (average thickness of the sealing material layer: 5 μm, average width of the sealing material layer: 400 μm) were formed on one surface of the glass substrate by the same method as in Example 1. Thus, a glass substrate with a sealing material layer was obtained. FIG. 2 is a photograph showing the glass substrate with a sealing material layer.

In addition, a silicon substrate (thermal expansion coefficient in the range of from 30° C. to 300° C.: 3.8 ppm/° C.) was prepared. Here, the ratio of the area in which the sealing material layer was formed with respect to the surface of the glass substrate on a side on which the sealing material layer was formed was 27%.

Next, the silicon substrate and the glass substrate with a sealing material layer were arranged so as to be laminated on each other through intermediation of the sealing material layer. After that, laser light was radiated from a glass substrate side to allow the sealing material layer to soften and deform, to thereby hermetically seal the glass substrate and the silicon substrate by the same method as in Example 1. Thus, a hermetic package group was obtained. Finally, the hermetic package group was divided through dicing so that each of the sealing patterns was not split. Thus, 100 hermetic packages were obtained.

### Example 3

A glass substrate with a sealing material layer and hermetic packages were obtained in the same manner as in Example 2 except that a glass substrate formed of alkali borosilicate glass (thermal expansion coefficient in the range of from 30° C. to 300° C.: 9.9 ppm/° C., □4 mm, thickness: 0.2 mm) was used in place of the glass substrate according to Example 2. The glass substrate comprises as a glass composition, in terms of mass %, 70.2% of SiO₂, 1.6% of Al₂O₃, 2.3% of B₂O₃, 9.6% of Na₂O, 9.1% of K₂O, 7.0% of BaO, 0.4% of Cl, 0.1% of SrO, 0.0001% of TiO₂, and 0.0001% of Fe₂O₃, has an average transmittance at a thickness of 0.2 mm in the range of from 250 nm or more to less than 300 nm of 89%, and has an average transmittance at a thickness of 0.2 mm in the range of from 300 nm or more to less than 1,000 nm of 92%.

### INDUSTRIAL APPLICABILITY

The hermetic package of the present invention is suitable as a hermetic package having mounted therein an electric device, such as a sensor chip or a UV LED. Other than the above, the hermetic package of the present invention is also suitably applicable to, for example, a hermetic package having housed therein, for example, a piezoelectric vibration device, or a wavelength conversion device in which quantum dots are dispersed in an organic resin.

### REFERENCE SIGNS LIST

1 hermetic package
10 glass substrate
11 package base
12 base part
13 recess
14 electric device
15 sealing material layer
16 top of recess
17 laser irradiation apparatus
L laser light

1. A glass substrate with a sealing material layer, comprising a glass substrate and a sealing material layer formed on the glass substrate,
wherein the glass substrate has an average transmittance at a thickness of 0.2 mm in a range of from 250 nm or more to less than 300 nm of 85% or more, and
wherein a difference in thermal expansion coefficient between the sealing material layer and the glass substrate in a temperature range of from 30° C. to 300° C. is 5 ppm/° C. or less.

2. The glass substrate with a sealing material layer according to claim 1, wherein a ratio of an area in which the sealing material layer is formed with respect to a surface of the glass substrate on a side on which the sealing material layer is formed is from 1% to 50%.

3. The glass substrate with a sealing material layer according to claim 1,
wherein the sealing material layer has a plurality of sealing patterns, and
wherein the sealing patterns each have a closed loop shape.

4. The glass substrate with a sealing material layer according to claim 1,
wherein the sealing material layer is a sintered body of composite powder containing at least bismuth-based glass powder and refractory filler powder, and
wherein the sealing material layer has a content of bismuth-based glass of from 65 vol % to 95 vol % and a content of a refractory filler of from 5 vol % to 35 vol %.

5. The glass substrate with a sealing material layer according to claim 1, wherein the sealing material layer is substantially free of a laser absorber.

6. The glass substrate with a sealing material layer according to claim 1,
wherein the sealing material layer has an average thickness of 15 μm or less, and
wherein a value obtained by dividing the average thickness of the sealing material layer by a thickness of the glass substrate is from 0.005 to 0.5.

7. The glass substrate with a sealing material layer according to claim 1,
wherein the sealing material layer has an average width of 1,000 μm or less, and
wherein a value obtained by dividing an average thickness of the sealing material layer by the average width of the sealing material layer is from 0.005 to 0.1.

8. The glass substrate with a sealing material layer according to claim 1, wherein the glass substrate has any shape of a rectangular shape, a circular shape, or a circular shape with an orientation flat.

9. The glass substrate with a sealing material layer according to claim 1, wherein the glass substrate has an antireflection film formed on any one surface thereof.

10. The glass substrate with a sealing material layer according to claim 1, wherein the glass substrate with a sealing material layer is used for sealing with laser light.

11. A method of producing a hermetic package, comprising the steps of:
preparing a package base;
preparing a glass substrate with a sealing material layer having a plurality of sealing patterns;
arranging the package base and the glass substrate with a sealing material layer so that the package base and the glass substrate with a sealing material layer are laminated on each other through intermediation of a sealing material layer;
radiating laser light from a glass substrate side to allow the sealing material layer to soften and deform, to thereby hermetically seal the glass substrate and the package base to provide a hermetic package group; and
dividing the hermetic package group to provide a plurality of hermetic packages,
wherein the glass substrate with a sealing material layer is the glass substrate with a sealing material layer of claim 1.

12. A hermetic package, comprising a glass substrate and a package base hermetically integrated with each other via a sealing material layer,
wherein the glass substrate has an average transmittance at a thickness of 0.2 mm in a range of from 250 nm or more to less than 300 nm of 85% or more, and
wherein a difference in thermal expansion coefficient between the sealing material layer and the glass substrate in a temperature range of from 30° C. to 300° C. is 5 ppm/° C. or less.
